(19) United States
(12) Patent Application Publication
(10) Pub. No.: US 2015/0268294 A1
(43) Pub. Date: Sep. 24, 2015

(54) PARALLEL MULTIPLEX TEST SYSTEM AND METHOD

(71) Applicants: LITE-ON ELECTRONICS (GUANGZHOU) LIMITED, Guangzhou (CN); LITE-ON TECHNOLOGY CORPORATION, TAIPEI CITY (TW)

(72) Inventors: TZUNG-NAN CHIANG, NEW TAIPEI CITY (TW); SHENG-HSIEN LIEN, NEW TAIPEI CITY (TW); KO-YUNG CHENG, NEW TAIPEI CITY (TW); XI-XIANG SONG, DONGGUAN CITY, GUANGDONG (CN); HSIEN-CHIEH FU, NEW TAIPEI CITY (TW)

(73) Assignee: LITE-ON ELECTRONICS (GUANGZHOU) LIMITED, Guangzhou (CN)

(21) Appl. No.: 14/263,072

(22) Filed: Apr. 28, 2014

(30) Foreign Application Priority Data
Mar. 18, 2014 (CN) 201410100929.1

(51) Int. Cl. G01R 31/28

(52) U.S. Cl. CPC G01R 31/28

(57) ABSTRACT

A parallel multiplex test system is disclosed. The parallel multiplex test system is used for testing N devices under test (DUTs) in the N isolation boxes via N test signals through N test channels. The parallel multiplex test system comprises a central processing unit and N function-test modules, wherein N is a positive integer greater than one. The parallel multiplex test system requests the function-test modules to take the function-tests for N DUTs according to the test items which have not been tested, so that different function-tests are taken for all of the DUTs simultaneously through different channels.

### BACKGROUND OF THE INVENTION

1. Field of the Invention

The instant disclosure relates to a test system and a test method; in particular, to a parallel multiplex test system and a parallel multiplex test method.

2. Description of Related Art

The reason why the testing machine always costs much is mainly related to the specific features regarding to the framework the traditional testing machine. Every testing machine producer has several frameworks of the testing machines. These frameworks owned by different producers, such as Advantest, Teradyne and Agilent, are not compatible. Also, even the different frameworks owned by the same producer are not compatible. Because of the compatibility, each testing machine needs to have own hardware and software which could not be applied to other testing machines Additionally, the program porting from one testing machine to another testing machine costs much, and developing a solving solution also costs a lot. Even though a solving solution is developed by a platform, the solving solution could not be ported to or reused on another platform. However, the program transformation from one platform to another platform is hard, definitely increases the spending time and efforts and has more testing cost.

### SUMMARY OF THE INVENTION

The instant disclosure provides a parallel multiplex test system, used for testing N devices under test (DUTs) in N isolation boxes via N test signals through N test channels. The parallel multiplex test system comprises a central processing unit and N function testing modules. The central processing unit determines test items which have not been tested regarding to the devices under test and transfers at least one identification signal for testing. The N function testing modules are electrically connected to the central processing unit. The function testing modules take function-tests for the corresponding devices under test according to the identification signal, and each function testing module takes different function-tests. In a time slot of a testing period, the parallel multiplex test system searches for the corresponding function testing modules so as to take function-tests for the devices under test according to the firmware such that different function-tests are taken for all of the devices under test simultaneously through different testing channels, wherein N is a positive integer greater than one. In another time slot of the testing period, the central processing unit determines test items which have not been tested regarding to the devices under test and transfers the identification signal to the corresponding function testing modules according to the firmware to deliver the testing signals through the testing channels so as to test the corresponding devices under test.

In one embodiment of the instant disclosure, the parallel multiplex test system comprises a RF distributor, a RF testing module, an audio testing module, a charge-coupled element, an infrared remote control module and a controller. The RF testing module comprises a vector signal analyzer and a vector signal generator. The RF testing module is electrically connected to the central processing unit. The RF testing module determines whether to take a RF functional test for the corresponding device under test according to the identification signal, wherein the RF testing module takes the RF functional test via the RF distributor. The audio testing module is electrically connected to the central processing unit and determines whether to take an audio functional test for the corresponding device under test according to the identification signal, wherein the audio testing module takes the audio functional test via a high definition multimedia interface switcher (HDMI switcher). The controller is electrically connected to the central processing unit. The controller determines whether to take an optical functional test for the corresponding device under test according to the identification signal, wherein the controller takes the optical functional test via the charge-coupled element and the infrared remote control module. During the testing period, the RF testing module, the audio testing module and the controller take the RF functional test, the audio functional test and the optical functional test for the devices under test in a parallel multiplex way according to the identification signal.

In one embodiment of the instant disclosure, the vector signal analyzer is configured to analyze the testing signal transferred by a transmitter of the corresponding device under test, and the vector signal generator is configured to generate and transfer a RF signal to a receiver of the corresponding device under test.

In one embodiment of the instant disclosure, the testing period has a time slot, and in the time slot, the RF testing module, the audio testing module and the controller simultaneously take function-tests for the corresponding devices under test respectively through the corresponding testing channels according to the identification signal.

In one embodiment of the instant disclosure, the parallel multiplex test system further comprises a RF switcher and a RF multiplexer. The RF switcher is electrically connected to the vector signal analyzer, the vector signal generator and the central processing unit. The RF multiplexer is electrically connected to the RF switcher and the central processing unit and determines to take the RF functional test for the corresponding device under test according to the identification signal. When the RF switcher determines to take the RF functional test for a transmitter of the corresponding device under test according to the identification signal, the parallel multiplex test system makes a RF signal analysis for the transmitter of the device under test via the RF distributor, the RF multiplexer, the RF switcher and the vector signal analyzer. When the RF switcher determines to take the RF functional test for a receiver of the corresponding device under test according to the identification signal, the parallel multiplex test system makes a RF signal analysis for the receiver of the device under test via the RF distributor, the RF multiplexer, the RF switcher and the vector signal generator.

The instant disclosure further provides a parallel multiplex test method. The parallel multiplex test method is used in a parallel multiplex test system and the parallel multiplex test system is used for testing N devices under test (DUTs) in N isolation boxes via N test signals through N test channels. The parallel multiplex test system comprises a central processing unit and N function testing modules. The N function testing modules are electrically connected to the central processing unit, wherein each function testing module takes different function-tests and N is a positive integer greater than one. The parallel multiplex test method comprises: determining test items which have not been tested regarding to the devices under test via the central processing unit and transferring at least one identification signal for testing; taking function-tests for the corresponding devices under test via N function testing modules according to the identification signal, wherein each function testing module takes different function-tests; searching for the corresponding function testing modules in a time slot of a testing period via the parallel multiplex test system so as to take function-tests for the devices under test according to the firmware such that different function-tests are taken for all of the devices under test simultaneously through different testing channels, wherein N is a positive integer greater than one; and determining test items which have not been tested regarding to the devices under test and transferring the identification signal to the corresponding function testing modules via the central processing unit according to the firmware in another time slot of the testing period to deliver the testing signals through the testing channels so as to test the corresponding devices under test.

To sum up, the parallel multiplex test system and method provided by the instant disclosure can integrate several function-tests into single machine so as to decrease the number of machines and further to save production testing cost, time consumption of test and human power.

In order to further the understanding regarding the instant disclosure, the following embodiments are provided along with illustrations to facilitate the disclosure of the instant disclosure.

### BRIEF DESCRIPTION OF THE DRAWINGS

FIG. 1 shows a schematic block diagram of a parallel multiplex test system according to an embodiment of the instant disclosure;

FIG. 2 shows a schematic diagram of the parallel testing of the parallel multiplex test system according to the embodiment of the instant disclosure shown in FIG. 1;

FIG. 3 shows a schematic block diagram of a parallel multiplex test system according to another embodiment of the instant disclosure;

FIG. 4 shows a schematic diagram of the parallel testing of the parallel multiplex test system according to the embodiment of the instant disclosure shown in FIG. 3; and

FIG. 5 shows a flow chart of a parallel multiplex test method according to an embodiment of the instant disclosure.

### DETAILED DESCRIPTION OF THE PREFERRED EMBODIMENTS

The aforementioned illustrations and following detailed descriptions are exemplary for the purpose of further explaining the scope of the instant disclosure. Other objectives and advantages related to the instant disclosure will be illustrated in the subsequent descriptions and appended drawings.

It will be understood that, although the terms first, second, third, and the like, may be used herein to describe various elements, components, regions, layers and/or sections, these elements, components, regions, layers and/or sections should not be limited by these terms. These terms are only to distinguish one element, component, region, layer or section from another region, layer or section discussed below could be termed a second element, component, region, layer or section without departing from the teachings of the instant disclosure. As used herein, the term “and/or” includes any and all combinations of one or more of the associated listed items.

[One Embodiment of a Parallel Multiplex Test System]

Generally speaking, when using a testing machine to take a test for the Device Under Test (DUT), such as the test for a mobile device, an isolation box would be used as an interface between the mobile device under test and the testing machine. The isolation box transfers all kinds of testing signals from the testing machine to mobile device under test and transfers the reaction of the mobile device under test to the testing machine so as to determine whether each tested function item of the mobile device is good.

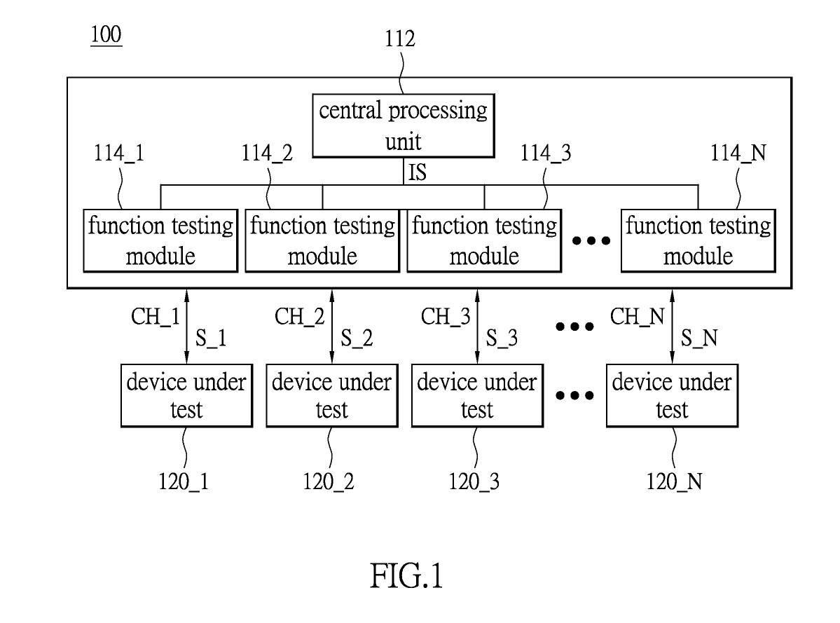

Please refer to FIG. 1, FIG. 1 shows a schematic block diagram of a parallel multiplex test system according to an embodiment of the instant disclosure. As shown in FIG. 1, in the present embodiment, the parallel multiplex test system 100 may be a testing machine for the mobile device. Also, the parallel multiplex test system 100 is used for testing N devices under test (Devices Under Test, DUTs) 120_1˜120_N in N isolation boxes (not shown) via N test signals S_1˜S_N through N test channels CH_1˜CH_N, wherein N is a positive integer greater than one. The parallel multiplex test system 100 comprises a central processing unit 112 and N function testing modules 114_1˜114_N. N function testing modules 114_1˜114_N are respectively electrically connected to the central processing unit 112.

Regarding to the central processing unit 112, the central processing unit 112 determines the test items which have not been tested regarding to the devices under test 120_1˜120_N and transfers at least one identification signal IS for testing, in other words, the identification signal IS has the relative information including testing order and tested function items of the N devices under test 120_1˜120_N. In the parallel multiplex test system 100, the central processing unit 112 is as a control center and organizes how the function testing modules 114_1˜114_N work according to the parallel testing operation designed by the designer (that is, the firmware) so as to start the function testing modules 114_1˜114_N simultaneously and further test a plurality of devices under test 120_1˜120_N in a parallel way.

Regarding to the function testing modules 114_1˜114_N, the function testing modules 114_1˜114_N take function-tests for the corresponding devices under test according to the identification signal IS transferred by the central processing unit 112. It should be noticed that, each of the function testing modules 114_1˜114_N takes different function-tests or has different testing signals. Also, in one embodiment, each of the function testing modules 114_1˜114_N could operate independently. The function-tests that the function testing modules 114_1˜114_N take may be, for example, a RF functional test, an audio functional test and an optical functional test, but it is not restricted thereto.

In the following description is further instruction in teaching a work mechanism of the parallel multiplex test system 100.

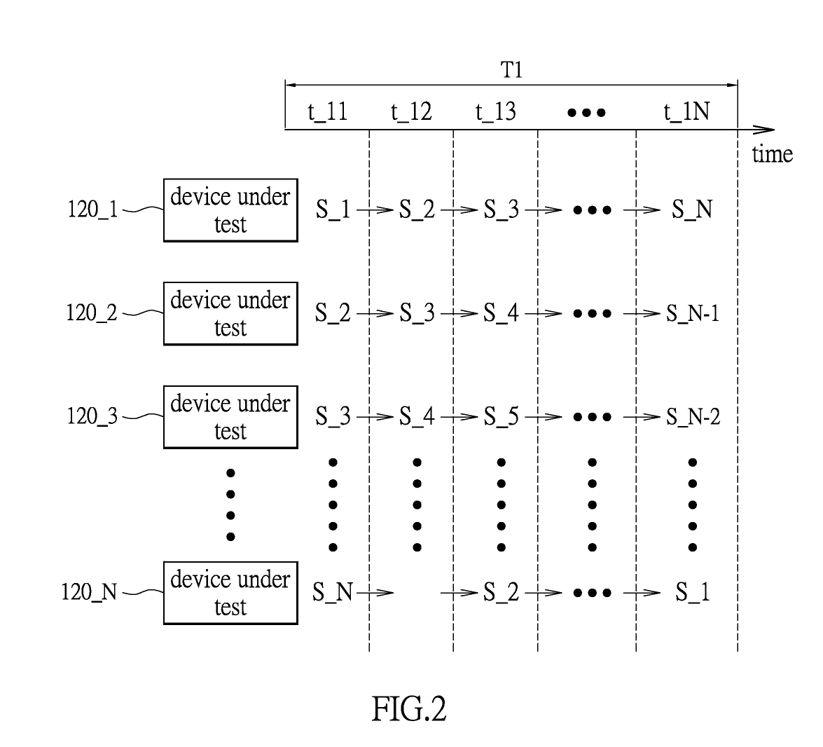

In the following description, it is to further disclose an operation of the parallel multiplex test system 100. Please refer to FIGS. 1 and 2 for further understanding of the instant disclosure if it is necessary. FIG. 2 shows a schematic diagram of the parallel testing of the parallel multiplex test system according to the embodiment of the instant disclosure shown in FIG. 1. During the testing period T1, the parallel multiplex test system 100 takes function-tests for the corresponding devices under test 120_1˜120_N according to the firmware in a parallel way so as to take different function-tests for all of the devices under test 120_1˜120_N simultaneously through different testing channels CH_1˜CH_N via the testing signal testing signal. In other words, during the testing period T1, the function testing modules 114_1˜114_N simultaneously takes function-tests for the corresponding devices under test 120_1˜120_N according to the identification signal IS transferred by the central processing unit 112 so as to simultaneously take different function-tests for all of the devices under test 120_1˜120_N through different testing channels CH_1˜CH_N. In other words, in a time slot of the testing period T1, the parallel multiplex test system 100 searches for the corresponding function testing module to take the corresponding function-test for the device under test according to the firmware such that all of the devices under test could have different function-tests simultaneously through different testing channels wherein N is a positive integer greater than one. Afterwards, in another time slot of the testing period T1, the central processing unit 112 determines the test item which have not been tested regarding to the devices under test according to the firmware and transfers the identification signal IS to the corresponding function testing module so as to deliver the testing signal for testing the devices under test through the testing channels.

For instance, in the present embodiment, there are N time slots t_11˜t_1N included in the testing period T1. Within the first time slot t_11, in the parallel multiplex test system 100, the first function testing module 114_{—}1 among the function testing modules 114_1˜114_N takes the first function-test (that is, the first test item) for the first device under test 120_1 according to the identification signal IS transferred by the central processing unit 112. The first function testing module 114_1 takes the function-test for the device under test 120_1 via the testing signal S_1 through the testing channel CH_1. Likewise, the central processing unit 112 determines the test item which have not been tested regarding to the device under test according to the firmware and transfers the identification signal to the corresponding function testing module. Therefore, within the first time slot t_{—}11 among the time slots t_11˜t_1N, the second function testing module 114_{—}2 among the function testing modules 114_1˜114_N takes the second function-test (that is, the second test item) for the second device under test 120_2 according to the identification signal IS transferred by the central processing unit 112. The second function testing module 114_2 takes the function-test for the device under test 120_2 via the testing signal S_2 through the testing channel CH_2. Similarly, the N^{th} function testing module 114_N among the function testing modules 114_1˜114_N takes the N^{th} function-test (that is, the N^{th} test item) for the N^{th} device under test 120_N according to the identification signal IS transferred by the central processing unit 112. The N^{th} function testing module 114_N takes the function-test for the device under test 120_N via the testing signal S_N through the testing channel CH_N.

Additionally, within the second time slot t_12, the parallel multiplex test system 100 begins to switch the tests orderly. Furthermore, the first function testing module 114_{—}1 among the function testing modules 114_1˜114_N takes the first function-test (that is, the first test item) for the second device under test 120_2 among the devices under test 120_1˜120_N according to the identification signal IS transferred by the central processing unit 112. In other words, the first function testing module 114_1 takes the function-test for the device under test 120_2 via the testing signal S_1 through the testing channel CH_1. Likewise, the central processing unit 112 determines the test items which have not been tested regarding to the device under test according to the firmware and transfers the identification signal IS to the corresponding function testing module. Therefore, within the first time slot t_{—}11 among the time slots t_11˜t_1N, the second function testing module 114_{—}2 among the function testing modules 114_1˜114_N takes the second function-test (that is, the second test item) for the third device under test 120_{—}3 among the devices under test 120_1˜120_N according to the identification signal IS transferred by the central processing unit 112. In other words, the second function testing module 114_2 takes function-test for the device under test 120_3 via the testing signal S_2 through the testing channel CH_2. Similarly, N^{th} function testing module 114_N among the function testing modules 114_1˜114_N takes the N^{th} function-test (that is, the N^{th} test item) for the first device under test 120_{—}1 among the devices under test 120_1˜120_N according to the identification signal IS transferred by the central processing unit 112. In other words, the N^{th} function testing module 114_N takes the function-test for the device under test 120_1 via the testing signal S_N through the testing channel CH_N.

Via the working mechanism mentioned above, the parallel multiplex test system 100 simultaneously takes different function-tests for all of the devices under test 120_1˜120 through different testing channels CH_1˜CH_N in each time slot according to the parallel testing operation (that is, the firmware). It is worth mentioning that, the relevant mechanism of the parallel multiplex test system 100 in another embodiment should be understood by the skilled in the art via the above description.

Additionally, after the testing period T1 ends, the parallel multiplex test system 100 enters into another testing period. For convenience, there is merely one testing period T1 in the embodiment shown in FIG. 2; however, in practice, the parallel multiplex test system 100 could have a plurality of testing periods and it is not restricted by disclosure of FIG. 2. After that, the parallel multiplex test system 100 requests the corresponding function testing module to take function-tests for all of the devices under test 120_1˜120_N in a parallel multiplex way (multi-channels) according to the test items which have not been tested regarding to the device under test. From the above, the instant disclosure could integrate many kinds of function-tests into single machine so as to decrease the number of machines, power consumption and working space and further to save the production cost, time consumption and human power.

For a specific instruction on an operation process of the parallel multiplex test system 100 of the instant disclosure, there is at least one of the embodiments for further instruction.

In the following embodiments, there are only parts different from embodiments in FIG. 1 described, and the omitted parts are indicated to be identical to the embodiments in FIG. 1. In addition, for an easy instruction, similar reference numbers or symbols refer to elements alike.

[Another Embodiment of the Parallel Multiplex Test System]

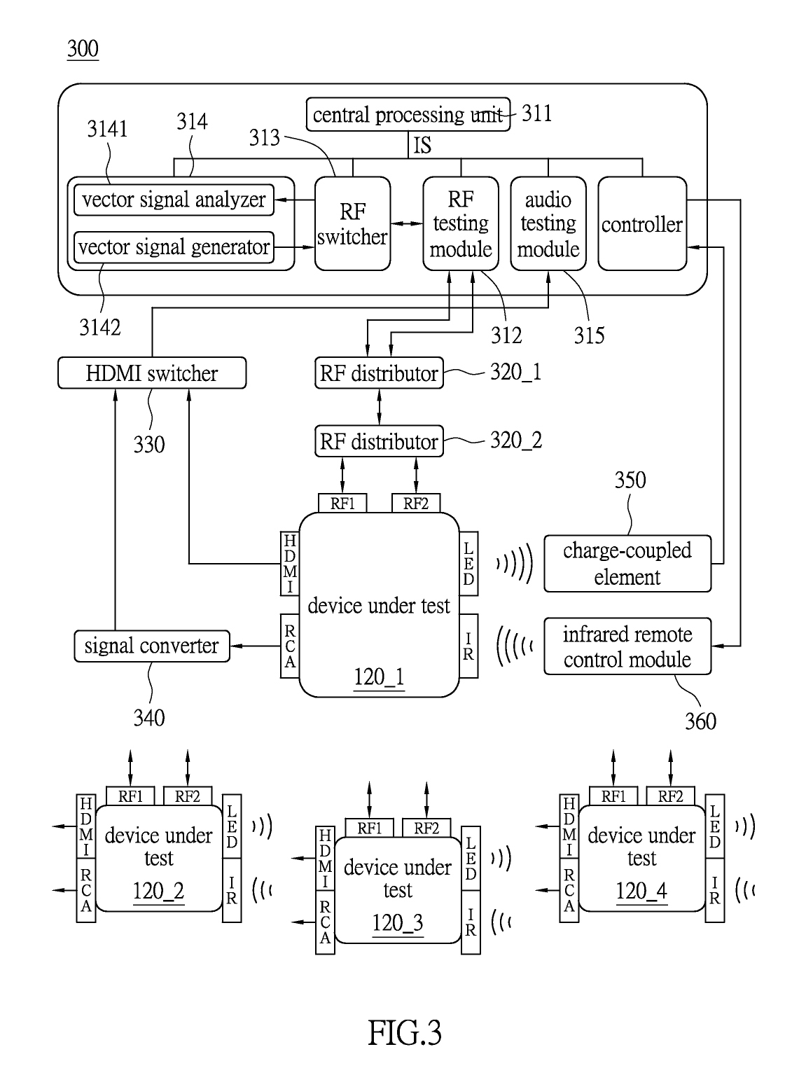

Please refer to FIG. 3, FIG. 3 shows a schematic block diagram of a parallel multiplex test system according to another embodiment of the instant disclosure. As shown in FIG. 3, the parallel multiplex test system 300 comprises a central processing unit 311, a RF testing module 314, a RF switcher 313, a RF multiplexer, an audio testing module 315 and a controller 316. The RF testing module 314 comprises a vector signal analyzer 3141 and a vector signal generator 3142. The RF testing module 314 is electrically connected to the central processing unit 311. The RF switcher 313 is electrically connected to the vector signal analyzer 3141, the vector signal generator 3142 and the central processing unit 311. The RF multiplexer 312 is electrically connected to the RF switcher 313 and the central processing unit 311. The audio testing module 315 is electrically connected to the central processing unit 311. The controller 316 is electrically connected to the central processing unit 311. In the present embodiment, the RF testing module 314, the RF switcher 313 and the RF multiplexer 312 are as an independent function testing module. The audio testing module 315 and the controller 316 are also two function testing modules in the parallel multiplex test system 300 respectively. The parallel multiplex test system 300 further comprises RF distributors 320_1 and 320_2, a charge-coupled element 350 and an infrared remote control module 360. The charge-coupled element 350 is electrically connected to the controller 316, and the infrared remote control module 360 is also electrically connected to the controller 316.

Regarding to the RF testing module 314, the RF testing module 314 determines whether to take the RF functional test for the corresponding device under test (one of the devices under test 120_1˜120_4) according to the identification signal IS transferred by the central processing unit 311, such as the transmitter or the receiver of the device under test, wherein the RF testing module 314 takes the RF functional test via the RF distributors 320_1 and 320_2.

Regarding to the vector signal analyzer 3141, the vector signal analyzer 3141 is configured to analyze the testing signal transferred by the transmitter of the corresponding device under test (one of the devices under test 120_1˜120_4), and herein the testing signal is a RF signal.

Regarding to the vector signal generator 3142, the vector signal generator 3142 is configured to generate and transfer a RF signal (that is, a testing signal) to the receiver of the corresponding device under test (one of the devices under test 120_1˜120_4).

Regarding to the RF switcher 313, when the RF switcher 313 determines to take the RF functional test for the transmitter of the corresponding device under test (one of the devices under test 120_1˜120_4) according to the identification signal IS transferred by the central processing unit 311, the parallel multiplex test system 300 analyzes the RF signal for the transmitter of the device under test via the RF distributors 320_1 and 320_2, the RF multiplexer 312, the RF switcher 313 and the vector signal analyzer 3141. When the RF switcher 313 determines to take the RF functional test for the receiver of the corresponding device under test according to the identification signal IS transferred by the central processing unit 311, the parallel multiplex test system 300 analyzes the RF signal for the receiver of the device under test via the RF distributors 320_1 and 320_2, the RF multiplexer 312, the RF switcher 313 and the vector signal generator 3141. Regarding to the RF multiplexer 312, the RF multiplexer 312 determines to take the RF functional test for the corresponding device under test (one of the devices under test 120_1˜120_4) according to the identification signal IS.

Regarding to the audio testing module 315, the audio testing module 315 takes the audio functional test for the corresponding device under test (one of the devices under test 120_1˜120_4) according to the identification signal IS. The audio testing module 315 takes the audio functional test via the High Definition Multimedia Interface (HDMI) switcher, wherein the HDMI is a full digital video and audio transmission interface which could transfer the uncompressed video and audio signals.

Regarding to the controller 316, the controller 316 determines to take the optical functional test for the corresponding device under test (one of the devices under test 120_1˜120_4) according to the identification signal IS, wherein the controller 316 takes the optical functional test via the charge-coupled element (such as charge-coupled device (CCD)) 350 and the infrared remote (IR remote) 360.

In the present embodiment, for a classic device under test, the parallel multiplex test system 300 applies the testing signals of all logic states to the input terminal of each device under test (DUT) so as to test each device under test (DUT). Via monitoring the generated signal as a response to the applied testing signal at the output terminals, it could be determined whether each device under test (DUT) is in an operating state as expected. During the testing period, in the parallel multiplex test system 300, the RF testing module 314, the RF switcher 313, the RF multiplexer 312, the audio testing module 315 and the controller 316 take the RF functional test, the audio functional test and the optical functional test for the devices under test 120_1˜120_4 in a parallel multiplex way according to the identification signal IS. The following description is going to further illustrate the working mechanism of the parallel multiplex test system during the testing period. Additionally, within a time slot of the testing period, the RF testing module 314, the RF testing module 313, the RF multiplexer 312, the audio testing module 315 and the controller 316 take the function-tests for the corresponding device under test (one of the devices under test 120_1˜120_4) respectively through corresponding testing channels (such as one of the testing channels CH_1˜CH_4 shown in FIG. 1) according to the identification signal IS.

In the following description is further instruction in teaching a work mechanism of the parallel multiplex test system 300.

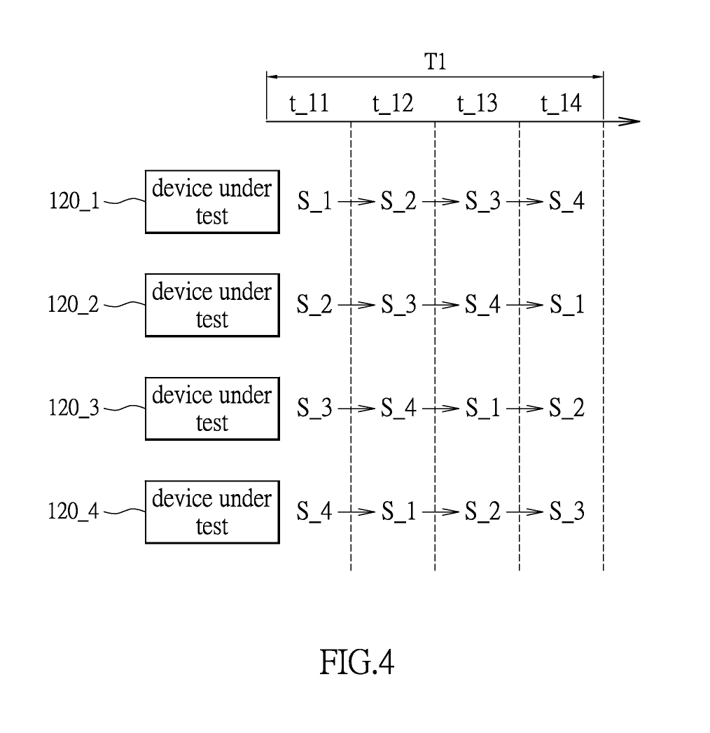

Please refer to FIGS. 3 and 4 for further understanding the working mechanism of the parallel multiplex test system 300 in the instant disclosure if it is necessary. FIG. 4 shows a schematic diagram of the parallel testing of the parallel multiplex test system according to the embodiment of the instant disclosure shown in FIG. 3. In the present embodiment, for convenience, assumed that N in the embodiments shown in FIG. 1 and FIG. 2 is 4. In other words, in the present embodiment, the parallel multiplex test system 300 tests four devices under test 120_1˜120_4 in a parallel way according to the parallel testing operation (that is, the firmware) designed by the designer. During the testing period T1, the parallel multiplex test system 300 takes the function-tests for the devices under test 120_1˜120_4 in a parallel multiplex way according to the firmware so as to take different function-tests for all of the devices under test 120_1˜120_4 simultaneously through the different testing channels CH_1˜CH_4 via the testing signals S_1˜S_4. In other words, during the testing period T1, in the parallel multiplex test system 300, the RF testing module 314, the RF switcher 313, the RF multiplexer 312, the audio testing module 315 and the controller 316 take the RF functional test, the RF functional test and the optical functional test for the devices under test 120_1˜120_4 simultaneously according to the identification signal IS transferred by the central processing unit 311 such that different function-tests could be taken for all of the devices under test 120_1˜120_4 through different testing channels CH_1˜CH_4 simultaneously. It is worth mentioning that, before taking tests in a parallel multiplex way, in the parallel multiplex test system 300, each of the devices under test 120_1˜120_4 is deposited in the isolation box by a robot arm and be turned on.

Furthermore, in the present embodiment, there are four time slots t_11˜t_14 included in the testing period T1. Within the first time slot t_11 among the time slots t_11˜t_14, one function testing module (not shown in FIG. 3) of the parallel multiplex test system 300 takes the first function-test for the device under test 120_1 according to the identification signal IS transferred by the central processing unit, wherein the first function-test is for the items including the power consumption rate and the bar code scan. Regarding to the function testing module for testing items including the power consumption rate and the bar code scan (not shown in FIG. 3), the function testing module takes the function-test for the device under test 120_1 via the testing signal S_1 through the testing channel CH_1.

As shown in FIG. 4, also, within the first time slot t_{—}11 among the time slots t_11˜t_14 (during the testing period T1), in the parallel multiplex test system 300, the RF testing module 314, the RF switcher 313 and the RF multiplexer 312 (the RF testing module 314, the RF switcher 313 and the RF multiplexer 312 are as an independent function testing module) according to the identification signal IS transferred by the central processing unit 311 take the RF functional test for the device under test 120_2. In other words, within the first time slot t_{—}11 among the time slots t_11˜t_14, the function testing module for testing items including the power consumption rate and the bar code scan, the RF testing module 314, the RF switcher 313 and the RF multiplexer 312 (the RF testing module 314, the RF switcher 313 and the RF multiplexer 312 are as an independent function testing module) take the RF functional test and the test for testing the power consumption rate and the bar code scan respectively through the testing channels CH_1 and CH_2 via the testing signals S_1 and S_2. Regarding to the details of the RF functional test, when the parallel multiplex test system 300 takes the RF functional test for the device under test 120_2, the RF switcher 313 and the RF multiplexer 312 orientates the testing path to the device under test 120_2 according to the identification signal IS. After that, the RF testing module 314 generates a testing signal via the vector signal generator 3142, tests the receiver of the device under test 120_2 via the RF switcher 313, the RF multiplexer 312 and the RF distributors 320_1 and 320_2, and transfers the reaction of the device under test 120_2 (as a response to the testing signal) back to the vector signal analyzer 3141 of the parallel multiplex test system 300 so as to determine whether the quality of the device under test 120_2 is good.

Moreover, in the same time slot t_11, the audio testing module 315 of the parallel multiplex test system 300 takes the audio functional test for the device under test 120_3 according to the identification signal IS transferred by the central processing unit 311. In other words, in the same time slot t_11, the function testing module for testing items including the power consumption rate and the bar code scan, the RF testing module 314, the RF switcher 313 and the RF multiplexer 312 (the RF testing module 314, the RF switcher 313 and the RF multiplexer 312 are as an independent function testing module) take the test for testing items including the power consumption rate and the bar code scan, the RF functional test and the audio functional test respectively through testing channels CH_1, CH_2 and CH_3 via the testing signals S_1, S_2 and S_3. Regarding to the details of the audio functional test, when the parallel multiplex test system 300 takes the audio functional test for the device under test 120_3, the device under test 120_3 transfers the HDMI signal to the audio testing module 315 via the HDMI switcher 330 so as to analyze the video signal. Besides, the device under test 120_3 transfers the RCA signal to the signal converter 340 to transform the RCA signal into the HDMI signal, and then transfers the HDMI signal to the audio testing module 315 via the HDMI switcher 330 so as to analyze the video signal.

Additionally, in the time slot t_11, the controller 316 of the parallel multiplex test system 300 takes the optical functional test for the device under test 120_4 according to the identification signal IS transferred by the central processing unit 311. In other words, within the time slot t_11, the function testing module for testing items including the power consumption rate and the bar code scan, the RF testing module 314, the RF switcher 313, the RF multiplexer 312 (the RF testing module 314, the RF switcher 313 and the RF multiplexer 312 are as an independent function testing module), the audio testing module 315 and the controller 316 take the test for testing items including the power consumption rate and the bar code scan, the RF functional test, the audio functional test and the optical functional test respectively through the testing channels CH_1, CH_2, CH_3 and CH_4 via the testing signals S_1, S_2, S_3 and S_4. Regarding to the details of the optical functional test, when the parallel multiplex test system 300 takes the optical functional test (such as LED or IR) for the device under test 120_4, the LED light of the device under test 120_4 would flash and the light signal would be transferred to the controller via the charge-coupled element 350 so as to have an analysis for the light signal. Also, the controller 316 further transfers another light signal and tests the infrared receiving terminal of the device under test 120_4 via the infrared remote control module 360.

Similarly, within the following time slots t_12, t_13 and t_14, each function testing module in the parallel multiplex test system 300 (including the controller 316) respectively takes and finishes each function-test listed above for the devices under test 120_1˜120_4 according to the identification signal IS transferred by the central processing unit 311.

Within the testing period T1, the function testing module for testing items including the power consumption rate and the bar code scan (not shown), the RF testing module 314, the RF switcher 313, the RF multiplexer 312 (the RF testing module 314, the RF switcher 313, the RF multiplexer 312 are as an independent function testing module), the audio testing module 315 and the controller 316 orderly take the test for testing items including the power consumption rate and the bar code scan, the RF functional test, the audio functional test and the optical functional test for the devices under test 120-_1˜120_4 according to the identification signal IS.

Additionally, for convenience, there is merely one testing period T1 shown in FIG. 4; however, in practice there could be a plurality of testing periods in the parallel multiplex test system 300 and it is not restricted by the embodiment shown in FIG. 4. Afterwards, the parallel multiplex test system 300 requests the corresponding function testing modules to test all of the devices under test 120_1˜120_4 in a parallel multiplex way (multi-channels) according to the test items which have not been tested. Furthermore, the program would automatically switch to the untested devices to test items which have not been tested for the devices under test 120_1, 120_2, 120_3 and 120_4. Regarding to the following testing periods, it should be able to be understood by the skilled via the working mechanism mentioned in the above embodiments, and thus there is no need to go further herein. From the above, the instant disclosure could integrate many function-tests into single machine so as to decrease the number of machine, the power consumption and the working space, and further save the production cost, testing time and human power. In one embodiment, 30% of the production cost is saved and 20% of the testing time is saved also.

[One Embodiment of a Parallel Multiplex Test Method]

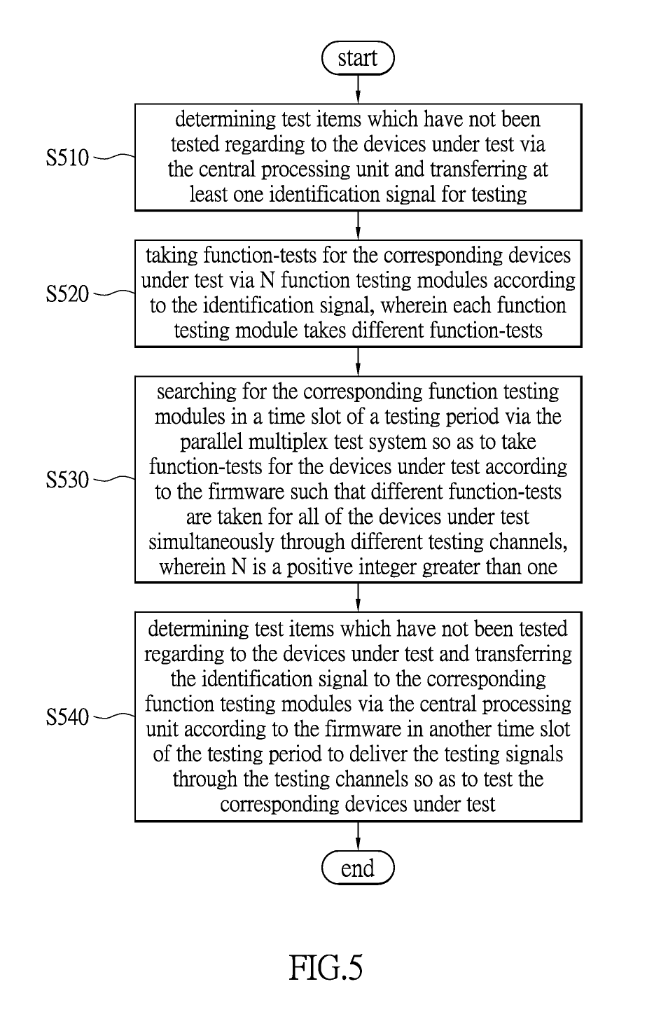

Please refer to FIG. 5, FIG. 5 shows a flow chart of a parallel multiplex test method according to an embodiment of the instant disclosure. The method of the present embodiment may be conducted in the parallel multiplex test system 100 or 300 shown in FIG. 1 or FIG. 3, and thus please refer to FIGS. 1-4 for further understanding. The parallel multiplex test method comprises steps as follows: determining test items which have not been tested regarding to the devices under test via the central processing unit and transferring at least one identification signal for testing (Step S510); taking function-tests for the corresponding devices under test via N function testing modules according to the identification signal, wherein each function testing module takes different function-tests (Step S520); searching for the corresponding function testing modules in a time slot of a testing period via the parallel multiplex test system so as to take function-tests for the devices under test according to the firmware such that different function-tests are taken for all of the devices under test simultaneously through different testing channels, wherein N is a positive integer greater than one (Step S530); and determining test items which have not been tested regarding to the devices under test and transferring the identification signal to the corresponding function testing modules via the central processing unit according to the firmware in another time slot of the testing period to deliver the testing signals through the testing channels so as to test the corresponding devices under test (Step S540).

Relevant details of the steps of the parallel multiplex test method regarding the parallel multiplex test system are described in the embodiments of FIGS. 1-4, and thus it is not repeated thereto. It is clarified that, a sequence of steps in FIG. 5 is set for a need to instruct easily, and thus the sequence of the steps is not used as a condition in demonstrating the embodiments of the instant disclosure.

To sum up, the parallel multiplex test system and method provided by the instant disclosure can integrate several function-tests into single machine so as to decrease the number of machines and further to save production testing cost, time consumption of test and human power.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A parallel multiplex test system, used for testing N devices under test (DUTs) in N isolation boxes with N test signals via N test channels, the parallel multiplex test system comprising:
a central processing unit, determining test items which have not been tested regarding to the devices under test according to a firmware and transferring at least one identification signal for testing; and
N function testing modules, electrically connected to the central processing unit, the function testing modules taking function-tests for the corresponding devices under test according to the identification signal, each function testing module taking different function-tests;
wherein in a time slot of a testing period the parallel multiplex test system searches for the corresponding function testing modules so as to take function-tests for the devices under test according to the firmware such that different function-tests are taken for all of the devices under test simultaneously through different testing channels, wherein N is a positive integer greater than one;
wherein in another time slot of the testing period the central processing unit determines test items which have not been tested regarding to the devices under test and transfers the identification signal to the corresponding function testing modules according to the firmware to deliver the testing signals through the testing channels so as to test the corresponding devices under test.

2. The parallel multiplex test system according to claim 1, further comprising:
an RF distributor;
an RF testing module, comprising a vector signal analyzer and a vector signal generator, the RF testing module electrically connected to the central processing unit, the RF testing module determining whether to take a RF functional test for the corresponding device under test according to the identification signal, wherein the RF testing module takes the RF functional test via the RF distributor;
an AV testing module, electrically connected to the central processing unit, the AV testing module determining whether to take an AV functional test for the corresponding device under test according to the identification signal, wherein the AV testing module takes the AV functional test via a high definition multimedia interface switcher (HDMI switcher);
a charge-coupled element;
an infrared remote control module; and
a controller, electrically connected to the central processing unit, the controller determining whether to take an optical functional test for the corresponding device under test according to the identification signal, wherein the controller takes the optical functional test via the charge-coupled element and the infrared remote control module;
wherein during the testing period, the RF testing module, the AV testing module and the controller take the RF functional test, the AV functional test and the optical functional test for the devices under test in a parallel multiplex way according to the identification signal.

3. The parallel multiplex test system according to claim 2, wherein the vector signal analyzer is configured to analyze the testing signal transferred by a transmitter of the corresponding device under test, and the vector signal generator is configured to generate an RF signal and transfer the RF signal to a receiver of the corresponding device under test.

4. The parallel multiplex test system according to claim 2, wherein in the time slot, the RF testing module, the AV testing module and the controller simultaneously take function-tests for the corresponding devices under test respectively through the corresponding testing channels according to the identification signal.

5. The parallel multiplex test system according to claim 2, further comprising:
an RF switcher, electrically connected to the vector signal analyzer, the vector signal generator and the central processing unit; and
an RF multiplexer, electrically connected to the RF switcher and the central processing unit, the RF multiplexer determining to take the RF functional test for the corresponding device under test according to the identification signal;
wherein when the RF switcher determines to take the RF functional test for a transmitter of the corresponding device under test according to the identification signal, the parallel multiplex test system makes an RF signal analysis for the transmitter of the device under test via the RF distributor, the RF multiplexer, the RF switcher and the vector signal analyzer;
wherein when the RF switcher determines to take the RF functional test for a receiver of the corresponding device under test according to the identification signal, the parallel multiplex test system makes an RF signal analysis for the receiver of the device under test via the RF distributor, the RF multiplexer, the RF switcher and the vector signal generator.

6. A parallel multiplex test method, used in a parallel multiplex test system, the parallel multiplex test system used for testing N devices under test (DUTs) in N isolation boxes with N test signals via N test channels, the parallel multiplex test system comprising a central processing unit and N function testing modules, the N function testing modules electrically connected to the central processing unit, wherein each function testing module takes different function-tests and N is a positive integer greater than one, the parallel multiplex test method comprising:
determining test items which have not been tested regarding to the devices under test via the central processing unit according to a firmware and transferring at least one identification signal for testing;
taking function-tests for the corresponding devices under test via N function testing modules according to the identification signal, wherein each function testing module takes different function-tests;
searching for the corresponding function testing modules in a time slot of a testing period via the parallel multiplex test system so as to take function-tests for the devices under test according to the firmware such that different function-tests are taken for all of the devices under test simultaneously through different testing channels, wherein N is a positive integer greater than one; and
determining test items which have not been tested regarding to the devices under test and transferring the identification signal to the corresponding function testing modules via the central processing unit according to the firmware in another time slot of the testing period to deliver the testing signals through the testing channels so as to test the corresponding devices under test.

7. The parallel multiplex test method according to claim 6, wherein the function testing modules comprise:
an RF distributor;
an RF testing module, comprising a vector signal analyzer and a vector signal generator, the RF testing module electrically connected to the central processing unit, the RF testing module determining whether to take a RF functional test for the corresponding device under test according to the identification signal, wherein the RF testing module takes the RF functional test via the RF distributor;
an AV testing module, electrically connected to the central processing unit, the AV testing module determining whether to take an AV functional test for the corresponding device under test according to the identification signal, wherein the AV testing module takes the AV functional test via a high definition multimedia interface switcher (HDMI switcher);
a charge-coupled element;
an infrared remote control module; and
a controller, electrically connected to the central processing unit, the controller determining whether to take an optical functional test for the corresponding device under test according to the identification signal, wherein the controller takes the optical functional test via the charge-coupled element and the infrared remote control module;
wherein during the testing period, the RF testing module, the AV testing module and the controller take the RF functional test, the AV functional test and the optical functional test for the devices under test in a parallel multiplex way according to the identification signal.

8. The parallel multiplex test method according to claim 7, wherein the vector signal analyzer is configured to analyze the testing signal transferred by a transmitter of the corresponding device under test, and the vector signal generator is configured to generate an RF signal and transfer the RF signal to a receiver of the corresponding device under test.

9. The parallel multiplex test method according to claim 7, wherein in the time slot, the RF testing module, the AV testing module and the controller simultaneously take function-tests for the corresponding devices under test respectively through the corresponding testing channels according to the identification signal.

10. The parallel multiplex test method according to claim 7,
wherein the parallel multiplex test system further comprises:
an RF switcher, electrically connected to the vector signal analyzer, the vector signal generator and the central processing unit; and
an RF multiplexer, electrically connected to the RF switcher and the central processing unit, the RF multiplexer determining to take the RF functional test for the corresponding device under test according to the identification signal;
wherein when the RF switcher determines to take the RF functional test for a transmitter of the corresponding device under test according to the identification signal, the parallel multiplex test system makes an RF signal analysis for the transmitter of the device under test via the RF distributor, the RF multiplexer, the RF switcher and the vector signal analyzer;
wherein when the RF switcher determines to take the RF functional test for a receiver of the corresponding device under test according to the identification signal, the parallel multiplex test system makes an RF signal analysis for the receiver of the device under test via the RF distributor, the RF multiplexer, the RF switcher and the vector signal generator.
